(19) United States
(12) Patent Application Publication
(10) Pub. No.: US 2015/0069485 A1
(43) Pub. Date: Mar. 12, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Akira YOTSUMOTO, Mie (JP); Kotaro FUJII, Nagasaki (JP); Hideki INOKUMA, Mie (JP); Akira MINO, Mie (JP)

(73) Assignee: KABUSHIKI KAISHA TOSHIBA, Tokyo (JP)

(21) Appl. No.: 14/195,785

(22) Filed: Mar. 3, 2014

(30) Foreign Application Priority Data
Sep. 11, 2013 (JP) 2013-188290

(51) Int. Cl. H01L 27/115

(52) U.S. Cl. CPC H01L 27/115
USPC 257/314; 438/675

(57) ABSTRACT

A semiconductor device includes memory cell units, each including memory cell transistors, a first transistor at a first end of the memory cell transistors, and a second transistor at a second end of the memory cell transistors. The memory cell units are arranged so that adjacent memory cell units have first transistors thereof facing each other or second transistors thereof facing each other, and so that a distance between the first transistors of the adjacent memory cell units is larger than a distance between the second transistors of the adjacent memory cell units. The semiconductor device further includes a first silicon nitride layer covering a first diffusion layer of the first transistors, a second silicon nitride layer covering a second diffusion layer of the second transistors. A thickness of the second silicon nitride layer is smaller than a thickness of the first silicon nitride layer.

### CROSS-REFERENCE TO RELATED APPLICATION

This application is based upon and claims the benefit of priority from Japanese Patent Application No. 2013-188290, filed Sep. 11, 2013, the entire contents of which are incorporated herein by reference.

### FIELD

Embodiments described herein relate generally to a semiconductor device and a method of manufacturing the same.

### BACKGROUND

Circuit elements of a semiconductor device have been shrunk to achieve a large memory capacity and low manufacturing cost. For example, in a memory device, wiring pitches of a bit line and a word line have been reduced. In such a memory device, for example, a hole pattern is formed to electrically connect the bit line and a diffusion layer of a drain-side gate select transistor, and a groove pattern is formed to electrically connect the source line and diffusion layer of source-side gate select transistor.

In order to form the hole and groove patterns, an etching process, for example, a reactive ion etching (RIE) method, is employed. During the etching process, the etching rate of the groove pattern may be higher than that of the hole pattern because of the geometry of the pattern. When the hole pattern and the groove pattern are simultaneously formed through the same etching process, the depth of the groove pattern may become too deep. As such, an etching may be extended too deeply in a semiconductor substrate, which may cause a junction leakage between the diffusion layer and the semiconductor substrate. To the contrary, when the depth of the groove pattern is appropriate, the depth of the hole pattern may be too shallow so that the hole pattern may not reach the semiconductor substrate.

### DESCRIPTION OF THE DRAWINGS

FIG. 1 is an example of an equivalent circuit diagram of a part of a memory cell array of a semiconductor device according to a first embodiment.

FIG. 2A is an example of a schematic plan view of a layout pattern of a part (periphery of a drain-side select gate transistor) of the memory cell region.

FIG. 2B is an example of a schematic plan view of a layout pattern of a part (periphery of a source-side select gate transistor) of the memory cell region.

FIG. 2C is an example of a schematic plan view of a layout pattern of a part of a peripheral circuit region.

FIGS. 3A-3C to 16A-16C each show a step of manufacturing process of a semiconductor device according to the first embodiment.

FIGS. 17A-17C to 25A-25C each show a step of manufacturing process of a semiconductor device according to a second embodiment.

### DETAILED DESCRIPTION

In general, according to one embodiment, a semiconductor device includes memory cell units, each including memory cell transistors arranged in a first direction above a substrate, a first transistor at a first end of the memory cell transistors, and a second transistor at a second end of the memory cell transistors. The memory cell units are arranged so that adjacent memory cell units have first transistors thereof facing each other in the first direction or second transistors thereof facing each other in the first direction, and so that a distance between the first transistors of the adjacent memory cell units is larger than a distance between the second transistors of the adjacent memory cell units. The semiconductor device further includes a first silicon nitride layer covering a first diffusion layer of the first transistors, a second silicon nitride layer covering a second diffusion layer of the second transistors, a source line electrically connected to at least one of the first transistors and the first diffusion layer, a bit line electrically connected to at least one of the second transistors and the second diffusion layer, a first contact electrically connecting the source line to the first diffusion layer, and a second contact electrically connecting the bit line to the second diffusion layer. A thickness of the second silicon nitride layer over the second diffusion layer is smaller than a thickness of the first silicon nitride layer over the first diffusion layer.

Hereinafter, plural embodiments will be described with reference to the drawings. In each of the embodiments, the same reference numerals refer to the same components, and the description thereof will be omitted. Incidentally, the drawings are schematically shown, and the relationship between a thickness and a plane dimension and a ratio of thickness of each layer may be different from a real magnitude.

### First Embodiment

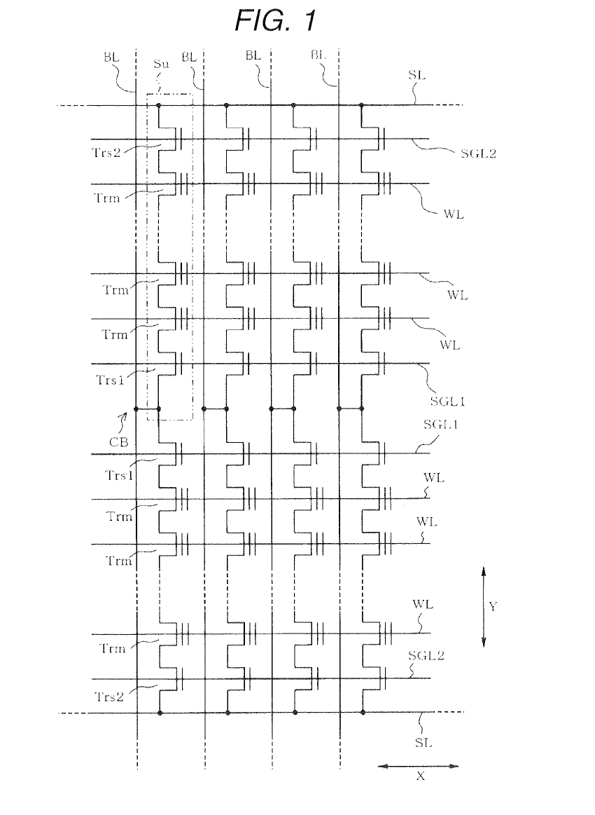

First, a configuration of an NAND type flash memory device will be described as an example of a semiconductor device according to an embodiment. FIG. 1 is an equivalent circuit diagram of a part of a memory cell array formed in a memory cell region of the NAND type flash memory device.

The memory cell array of the NAND type flash memory device includes NAND cell units SU formed in a matrix layout. Each NAND cell unit SU includes two select gate transistors Trs1 and Trs2, and plural (for example, 32) memory cell transistors Trm connected in series between the select gate transistors Trs1 and Trs2. In the NAND cell unit SU, the plural memory cell transistors Trm are formed in such a manner that each pair of adjacent memory cell transistors Trm shares a source or drain region.

Gate electrodes of the memory cell transistors Trm arranged in an X direction (corresponding to a word line direction and a gate width direction) in FIG. 1 are connected to a common word line (control gate line) WL. In addition, gate electrodes of the select gate transistors Trs1 extending in the X direction in FIG. 1 are connected to a common select gate line SGL1, and gate electrodes of the select gate transistors Trs2 are connected to a common select gate line SGL2. A bit line contact CB is connected to a drain region of one of the select gate transistors Trs1. The bit line contact CB is connected to a bit line BL extending in a Y direction (corresponding to a gate length direction and a bit line direction) orthogonal to the X direction in FIG. 1. Furthermore, a source region of each select gate transistor Trs2 is connected to a source line SL extending in the X direction in FIG. 1 via the source region.

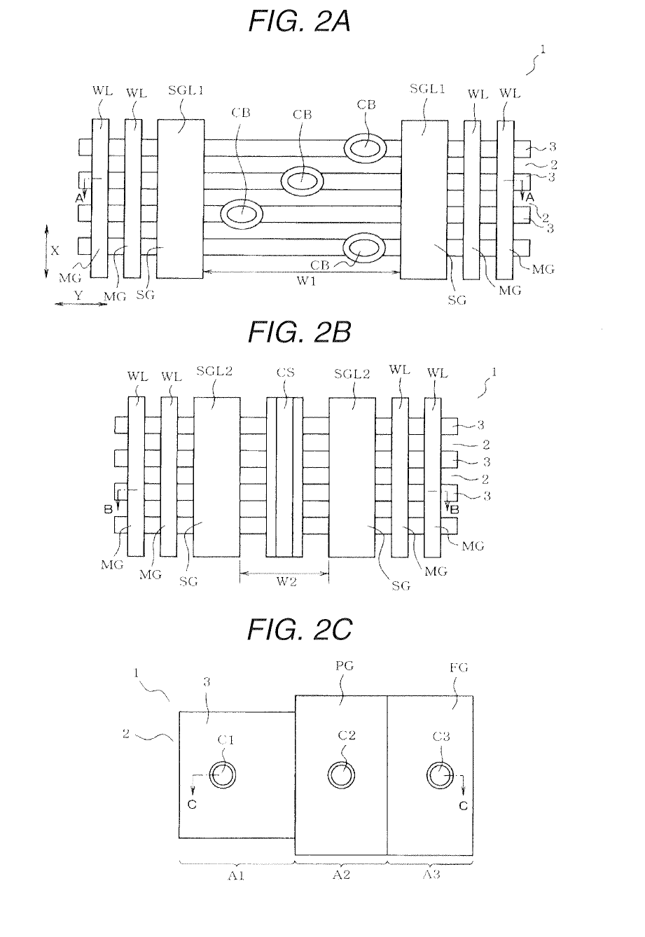

FIGS. 2A and 2B show layout patterns of parts of the memory cell region, and FIG. 2C shows a layout pattern of a part of a peripheral circuit region. In FIGS. 2A and 2B, as element isolation regions, plural shallow trench isolations (STIs) 2 extending in the Y direction in FIGS. 2A and 2B are formed in a silicon substrate (semiconductor substrate) 1 at predetermined intervals in the X direction in FIGS. 2A and 2B. Thereby, element regions 3 extending in the Y direction in FIGS. 2A and 2B are formed in such a manner that the element regions are isolated from each other in the X direction in FIGS. 2A and 2B. The word lines WL of the memory cell transistors are formed in such manner that the word lines extend in a direction orthogonal to the element regions 3 (in the X direction in FIGS. 2A and 2B), and at predetermined intervals in the Y direction in FIGS. 2A and 2B. In this case, the word lines WL and the element regions 3 are formed in a lattice shape, and they form an NAND column in which the thirty two word lines WL are arranged for one set.

In addition, the select gate line SGL1 and SGL2 of the select gate transistor are formed at different ends of the NAND column. The select gate line SGL1 is disposed on the drain side of the NAND column and the select gate line SGL2 is disposed on the source side of the NAND column. The NAND columns are disposed such that the drain sides of the two adjacent NAND columns are adjacent to each other and the source sides of the two adjacent NAND columns are adjacent to each other. Bit line contacts CB are formed in the respective element regions 3 between a pair of the two adjacent select gate lines SGL1. The bit line contacts CB are arranged in a so-called “three continuous zigzag shape” by alternately arranging three columns of holes in the bit line direction (Y direction). The bit line contacts CB are formed in an elliptical shape in which a major axis extends in the bit line direction. In addition, two columns of the holes may be alternately arranged in the bit line direction (Y direction), or four or more columns of the holes may be arranged.

Source line contacts CS are formed in the respective element regions 3 between the pair of the two adjacent select gate lines SGL2. The source line contact CS differs from the bit line contact CB in that the layout pattern is a line-shaped pattern extending in the word line direction and having a single linear shape formed in a groove, that is, a groove wiring local interconnect (LI).

In the above-described configuration, the orientation of the NAND columns is reversed in every other NAND column, so that the bit line contact CB and the source line contact CS are shaded by adjacent two NAND columns. The above-described NAND columns are continuously formed and form the cell array. In addition, at the intersection of the word line WL and the element region 3, a gate electrode MG of the memory cell transistor is formed, and at the intersection of the select gate lines SGL1 and SGL2 and the element region 3, a gate electrode SG of the select gate transistor is formed.

In the above-described configuration, an interval W1 between drain-side select gate electrodes SG of two adjacent drain-side select gate transistors is wider than an interval W2 between source-side select gate electrodes SG of two adjacent source-side select gate transistors.

As shown in FIG. 2C, in a peripheral circuit region of the silicon substrate, STIs 2, serving as an element isolation region, are formed so as to surround the element region 3, which is an element forming region. On the element region 3, a gate electrode PG of a peripheral element is formed. In the right side of the gate electrode PG in FIG. 2C, the upper portion of a floating gate electrode FG, configuring a lower electrode of the gate electrode PG, is exposed.

Then, a first contact C1 is formed in the upper portion of the element region 3, a second contact C2 is formed in the upper portion of the gate electrode PG, and a third contact C3 is formed in the upper portion of the floating gate electrode FG. Here, the element region 3 is referred to as a region A1, the gate electrode PG is referred to as a region A2, and the lower electrode portion is referred to as a region A3.

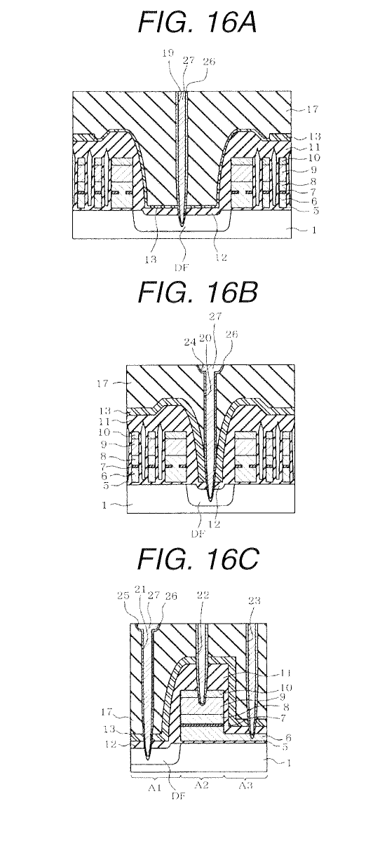

FIG. 16A is a schematic cross-sectional view of an example of a drain-side memory cell region taken along the line A-A of FIG. 2A. FIG. 16B is a schematic cross-sectional view of an example of a source-side memory cell region taken along the line B-B of FIG. 2B. FIG. 16C is a schematic cross-sectional view of an example of a peripheral circuit region taken along the line C-C of FIG. 2C.

As shown in FIGS. 16A and 16B, for example, a gate oxide film 5, as a gate insulating film, is formed on the upper surface of the silicon substrate 1. Plural NAND cell units are formed on the upper surface of the gate oxide film 5. The gate electrodes MG of the memory cell transistors are formed at predetermined intervals. The select gate electrode SG of the source-side select gate transistor is disposed adjacent to the gate electrode disposed at one end of the arrayed gate electrodes MG of the plural memory cell transistor, and the select gate electrode SG of the drain-side select gate transistor is disposed adjacent to the gate electrode disposed at the other end of the arrayed gate electrodes MG of the memory cell transistors. The select gate electrodes SG of the source-side select gate transistors of two adjacent NAND cell units are arranged adjacently to each other and the select gate electrodes SG of the drain-side select gate transistors of two adjacent NAND cell units are arranged adjacently to each other. An interval between the drain-side select gate electrodes SG of the drain-side select gate transistors is wider than an interval between the source-side select gate electrodes SG of the source-side select gate transistors.

The gate electrode MG of the memory cell is formed by sequentially laminating a polysilicon film 6 used for the floating gate electrode FG (charge storage layer), an interelectrode insulating film (inter-poly insulating film) 7 made of an ONO film or NONON film, a polysilicon film 8 and a tungsten film 9 used for a control gate electrode CG, and a cap film 10. The select gate electrodes SG of the drain-side select gate transistor and the source-side select gate transistor are made of substantially the same material as the constituent material of the gate electrode MG of the memory cell and have substantially the same structure as the structure of the gate electrode MG of the memory cell. However, an opening is formed in the center of the interelectrode insulating film 7 formed in the select gate electrodes SG, and the floating gate electrode FG and the control gate electrode CG are electrically connected via the opening.

The gate electrodes MG and the select gate electrodes SG are formed by dividing the layers 6-10 into plural portions in a horizontal direction in FIGS. 16A and 16B. A diffusion layer DF is formed between the select gate electrodes SG in the surface region of the silicon substrate 1. In addition, a diffusion layer (not shown) is formed between the two adjacent gate electrodes MG and between the gate electrode MG and the select gate electrode SG in the surface region of the silicon substrate 1. These diffusion layers are source and drain regions.

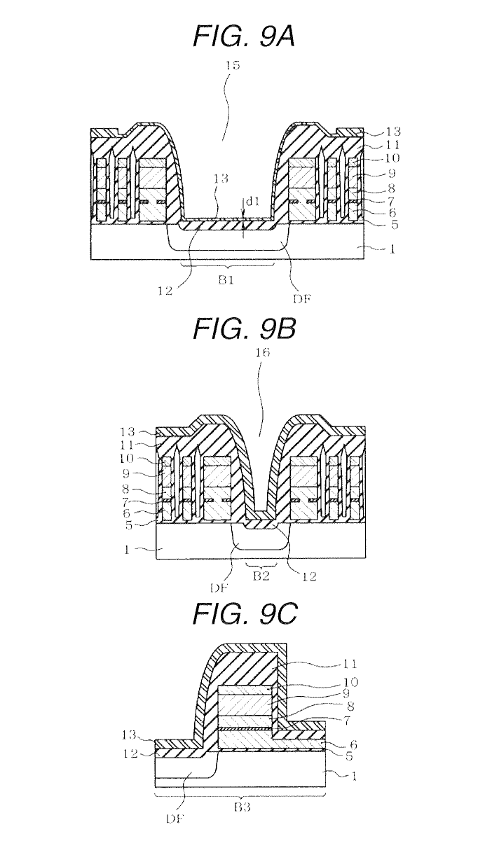

A silicon oxide film 11 used for a spacer is formed on the side wall and the upper surface of the gate electrode MG and the side wall and the upper surface of the select gate electrode SG. An air gap AG is formed between the two adjacent gate electrodes MG and between the gate electrode MG and the select gate electrode SG. A liner silicon oxide film 12 is formed between the adjacent select gate electrodes SG on the silicon oxide film 11. On the liner silicon oxide film 12, a liner silicon nitride film 13 is formed. The thickness of the liner silicon nitride film 13 is small at a bottom surface and side surface in a concave portion 15 (refer to FIG. 9A) in which the bit line contact GB are formed. That is, the thickness of a portion of the liner silicon nitride film 13 formed in a drain-side region is smaller than the thickness of a portion of the liner silicon nitride film 13 formed in a source-side region. On the liner silicon nitride film 13, a first interlayer insulating film (for example, a non-doped silicate glass (NSG) film) 17 is formed.

In addition, the thickness of the silicon oxide film 11 on the select gate electrode SG is greater than the thickness of the silicon oxide film 11 on the gate electrode MG. Here, the thickness of the liner silicon nitride film 13 formed on the select gate electrodes SG in the drain-side region (shown in FIG. 16A) is smaller than the thickness of the liner silicon nitride film 13 formed on the select gate electrodes SG in the source-side region (shown in FIG. 16B). Further, the thickness of the liner silicon nitride film 13 formed in the drain-side region (FIG. 16A) is smaller also on the select gate electrode SG. The thickness of the liner silicon nitride film 13 formed in the drain-side region may be also smaller on the gate electrode MG as shown in FIG. 16A.

As shown in FIG. 16C, the gate electrode PG of the peripheral circuit region has substantially the same configuration as the configuration of the gate electrode MG of the memory cell region. Thus, the gate electrode PG of the peripheral circuit region is formed by sequentially laminating the polysilicon film 6 used for the floating gate electrode FG, the interelectrode insulating film 7, the polysilicon film 8 and the tungsten film 9 used for the control gate electrode CG, and the cap film 10. The diffusion layer DF is formed in the element region (between the gate electrodes PG) A1 in the surface portion of the silicon substrate 1. The silicon oxide film 11 used for the spacer is formed on the side wall and the upper surface of the gate electrode PG on the region A1 side. The liner silicon oxide film 12 is formed on the upper surface of the silicon substrate 1 in the region A1, on the silicon oxide film 11 formed on the side wall and the top of the gate electrode PG in the region A2, and the upper surface of the polysilicon film 6 in the region A3. On the liner silicon oxide film 12, the liner silicon nitride film 13 is formed. On the liner silicon nitride film 13, the first interlayer insulating film 17 is formed.

In addition, as shown in FIG. 16A, a hole 19 for the bit line contact CB is formed between the two adjacent drain-side select gate electrodes SG so that the hole reaches the upper surface of the silicon substrate 1. In the hole 19, a barrier metal 26 and a portion of the tungsten film 27 are embedded. Then, as shown in FIG. 16B, a groove 20 for the source line contact CS is formed between the two adjacent source-side select gate electrodes SG so that the groove reaches the upper surface of the silicon substrate 1. In the groove 20, the barrier metal 26 and a portion of the tungsten film 27 are embedded.

Further, as shown in FIG. 16C, holes 21, 22, and 23 for forming the three contacts C1, C2, and C3 of the peripheral circuit region, respectively, are formed in the three regions A1, A2, and A3 of the peripheral circuit region. The hole 21 is formed so as to reach the upper surface of the silicon substrate 1. The hole 22 is formed so as to reach the tungsten film 9. The hole 23 is formed so as to reach the polysilicon film 6. In the holes 21, 22, and 23, the barrier metal 26 and a portion of the tungsten film 27 are embedded. In addition, the thickness of the liner silicon nitride film 13 formed on the upper surface of the silicon substrate 1 in the drain-side region (FIG. 16A) is smaller than the thickness of the liner silicon nitride film 13 formed in the region A1 of the peripheral circuit region (FIG. 16C).

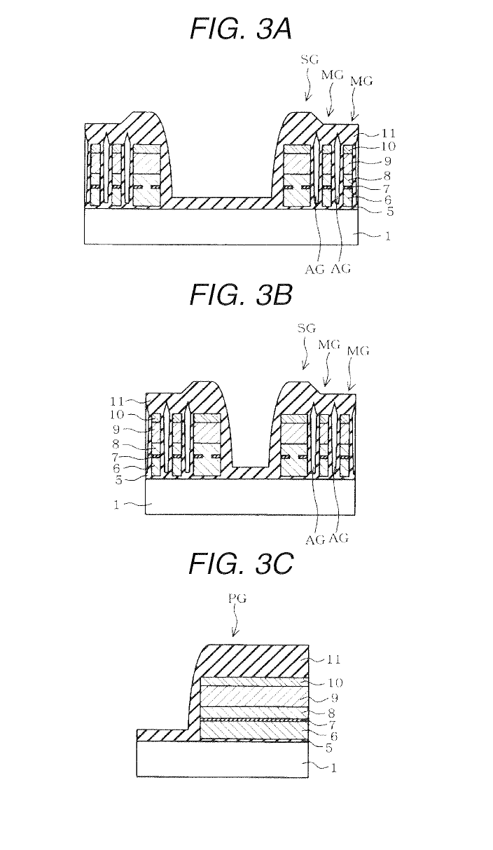

Next, manufacturing processes of the above-described NAND type flash memory device from a step of forming gates to a step of forming bit line contacts CB, source line contacts CS, and each contact C1, C2 and C3 will be described with reference to FIGS. 3A to 16C (descriptions of preceding and following steps of the above processes will be omitted). In addition, FIGS. 3A to 16A are cross-sectional views (cross-sectional views taken along the line A-A in FIG. 2A) of the peripheral portion around the bit line contact CB. FIGS. 3B to 16B are cross-sectional views (cross-sectional views taken along the line B-B in FIG. 2B) of the peripheral portion around the source line contact CS. FIGS. 3C to 16C are cross-sectional views (cross-sectional views taken along the line C-C in FIG. 2C) of the peripheral portion around each contact C1, C2 and C3 of the peripheral element.

First, as shown in FIGS. 3A to 3C, the gate oxide film 5, the polysilicon film 6 to be used for the floating gate electrode FG (charge storage layer), the interelectrode insulating film (inter-poly insulating film) 7 made of an ONO film or NONON film, the polysilicon film 8 and the tungsten film 9 to be used for the control gate electrode CG, and the cap film 10 are sequentially laminated on the silicon substrate 1. Then, the gate electrodes MG of the memory cell transistors and the select gate electrodes SG, and the gate electrodes PG of the peripheral elements are formed by patterning the laminated films using a photolithography method and RIE method. Then, the air gap AG may be provided between the two adjacent gate electrodes MG of the memory cell transistor, and between the gate electrode MG and the select gate electrode SG. Further, the silicon oxide film 11 used for the spacer is formed as shown in FIGS. 3A to 3C. Here, by adjusting film forming conditions of the silicon oxide film 11, the air gap Ag can be formed between the adjacent two gate electrodes MG and between the gate electrode MG and the select gate electrode SG.

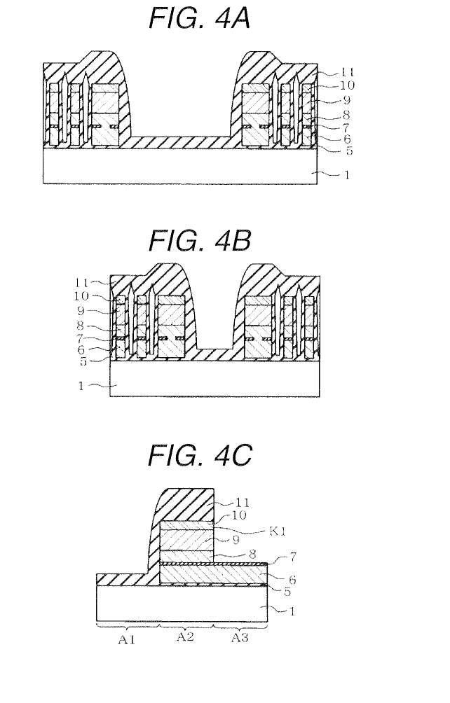

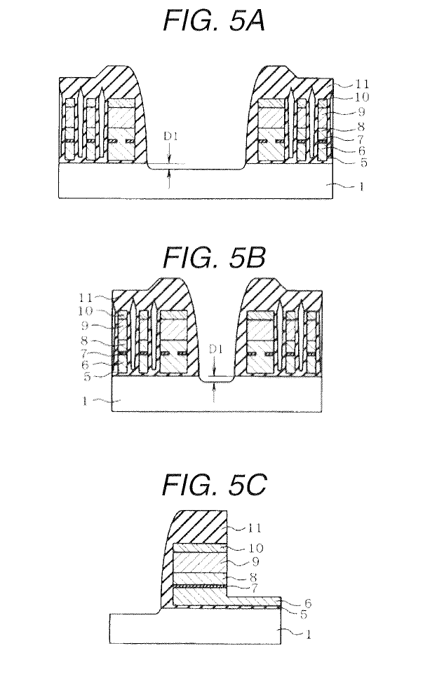

Next, as shown in FIG. 4C, the gate electrode PG of the peripheral element in the region A3 is removed using the photolithography method and RIE method. For example, the polysilicon film 8 and the tungsten film 9 used for the control gate electrode CG and the cap film 10 are removed to form an opening K1 in which the upper surface of the interelectrode insulating film 7 is exposed. Here, in the opening K1, the side surface of the polysilicon film 8, the tungsten film 9, and the cap film 10 are exposed as well. The upper surface of the silicon substrate 1 between the select gate electrodes SG is engraved, and a step D1 (refer to FIGS. 5A to 5C) is formed in some cases.

Then, as shown in FIGS. 5A to 5C, the silicon oxide film 11 is etched using an anisotropic RIE method. As a result, a portion of the silicon oxide film 11 between the pair of the select gate electrodes SG in the memory cell region is removed, and the upper surface of the silicon substrate 1 in the peripheral circuit region is exposed. At the same time, the right-side portion of the interelectrode insulating film 7 in the gate electrode PG of the peripheral element is removed so that the right-side portion of the upper surface of the polysilicon film 6 for the floating gate electrode FG may be exposed.

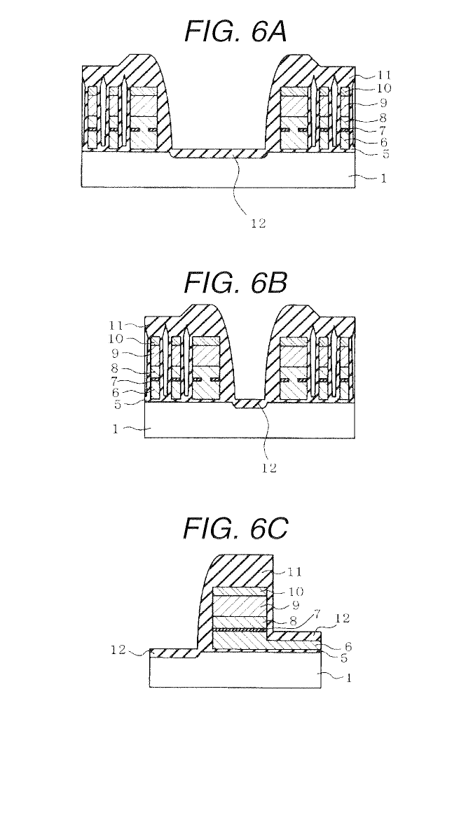

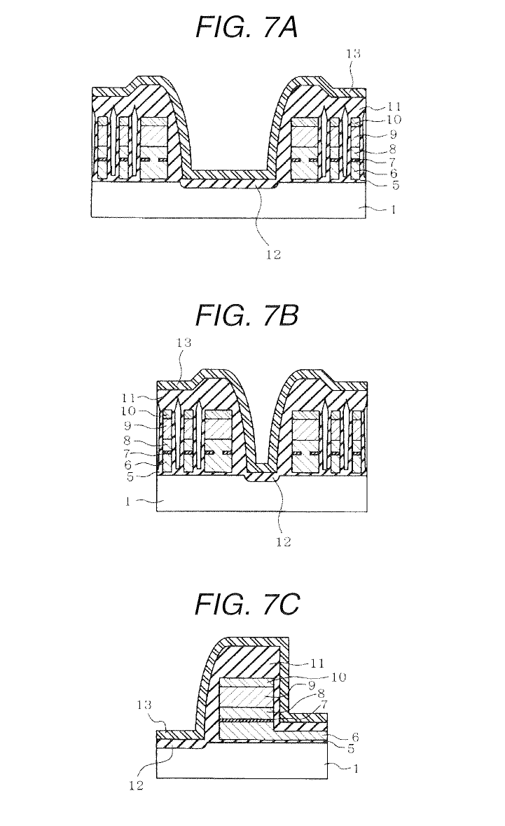

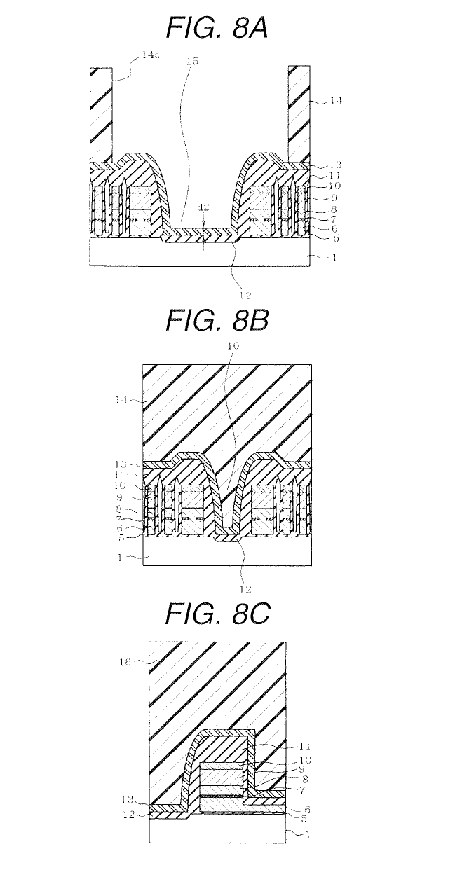

As shown in FIGS. 6A to 6C, the liner silicon oxide film 12 is formed between the two adjacent select gate electrodes SG, on the silicon oxide film 11, on the side surface of the gate electrode PG exposed from the opening K1, and on the floating gate electrode FG. Here, the liner silicon oxide film 12 is formed so as to have a thickness such that a space between the select gate electrodes SG is not completely filled with the liner silicon oxide film 12. Subsequently, as shown in FIGS. 7A to 7C, the liner silicon nitride film 13 having a thickness of, for example, about 30 nm to 40 nm is formed on the liner silicon oxide film 12. Here, the liner silicon nitride film 13 is formed so as to have a thickness such that the space between the select gate electrodes SG is not completely filled with the liner silicon nitride film 13.

Then, a resist 14 (FIGS. 8A and 8C) is formed. Then, an opening portion 14a is formed in the resist 14 so as to correspond to a drain-side region, that is, the concave portion 15 for forming a bit line contact CB, using the photolithography method (FIG. 8A). The opening portion 14a corresponds to a region between the two adjacent select gate electrodes SG of the select gate transistor between which the bit line contact CB is formed on the surface of the silicon substrate 1. Also, a source-side region, that is, the concave portion 16 in which a source line contact CS is formed is covered by the resist 14 (FIG. 8B). In addition, the regions A1 to A3 in which each contact C1, C2, and C3 of the peripheral element is formed are covered by the resist 14 (FIG. 8C).

Next, using the RIE method, a process of reducing the thickness of the liner silicon nitride film 13 is performed. This process causes thickness the liner silicon nitride film 13, at the drain region, that is, the bottom and side surfaces in the concave portion 15 for forming the bit line contact CB, above the upper surface of the select gate electrode SG, and above the upper surface of the gate electrode MG (FIG. 9A). Through this process, the thickness of the portions of the liner silicon nitride film 13 decreases by, for example, about 15 nm. That is, when a thickness of the liner silicon nitride film 13 in the bottom portion of the concave portion 15 as shown in FIG. 9A is referred to as d1, and a thickness of the liner silicon nitride film 13 before the process as shown in FIG. 8A is referred to as d2, the liner silicon nitride film is processed such that a distance (d2+d1) is about 15 nm. In addition, the liner silicon nitride film 13 on the side portions of the concave portion 15 is processed to be thinner by, for example, about 10 nm. FIGS. 9A to 9C show a state in which the resist 14 is removed.

The diffusion layer DF is formed between the select gate electrodes SG during the preceding or following step of the process.

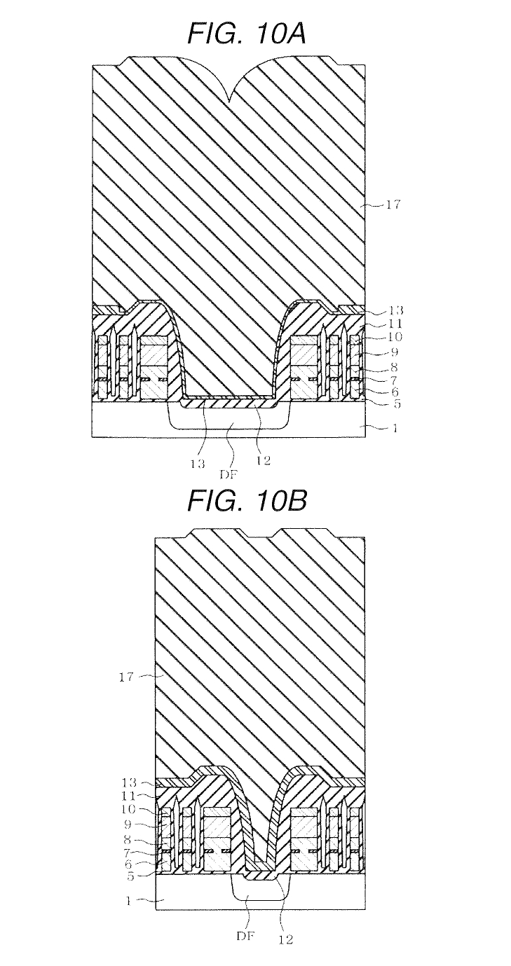

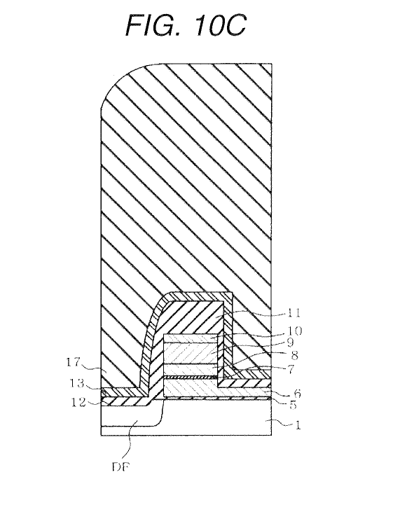

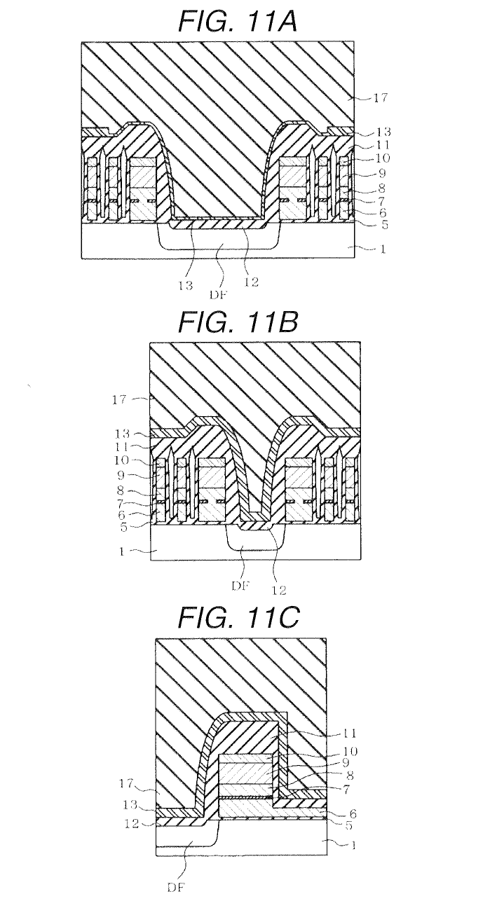

Next, as shown in FIGS. 10A to 10C, for example, the non-doped silicate glass (NSG) film 17 is formed, as the first interlayer insulating film, on the liner silicon nitride film 13. Then, as shown in FIGS. 11A to 11C, a process of flattening the upper surface of the NSG film 17 is performed using a chemical mechanical polish (CMP) method.

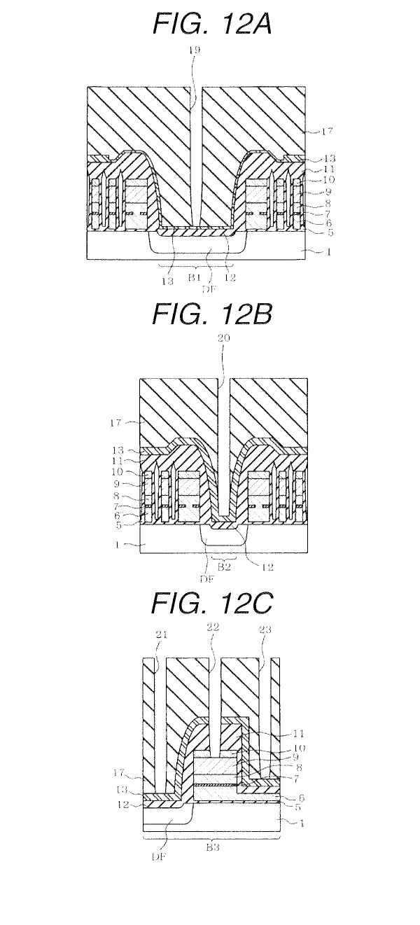

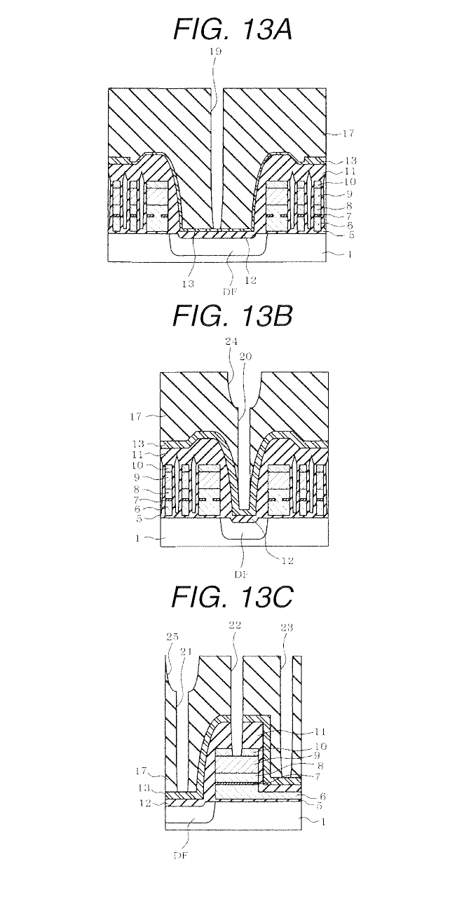

Subsequently, various contact patterns, that is, a hole pattern (drain region) for the bit line contact CB, a groove pattern (source region) for the source line contact CS, and a hole pattern for the three contacts C1, C2, and C3 in the peripheral circuit region are formed using the lithography method, and then, the first interlayer insulating film (NSG film) 17 is processed (FIGS. 12A to 12C) using the RIE method. In the process, etching is performed under conditions in which the silicon nitride film is not easily etched. As a result, the respective bottom portions of the holes may be adjusted on the upper surface of the liner silicon nitride film 13. Further, the bottom portion of the hole 22 is positioned on the upper surface of the tungsten film 9 by adjusting the etching conditions.

Then, a pattern for forming a groove 24 for a wiring layer that is formed in the upper portion of the line-shaped groove 20 for the source line contact CS, and a pattern for forming a groove 25 for the wiring layer that is formed in the upper portion of the hole 21 of the first contact C1 in the peripheral circuit region is formed using the lithography method. Then, the first interlayer insulating film 17 is processed using the RIE method (FIGS. 13A to 13C). Through this process, the groove 24 for the wiring layer is formed in the upper portion of the line-shaped groove 20 for the source line contact CS (FIG. 13B), and the groove 25 for the wiring layer is formed in the upper portion of the hole 21 of the first contact C1 in the peripheral circuit region (FIG. 13C). Grooves may be formed in the upper portion of the holes 22 and 23.

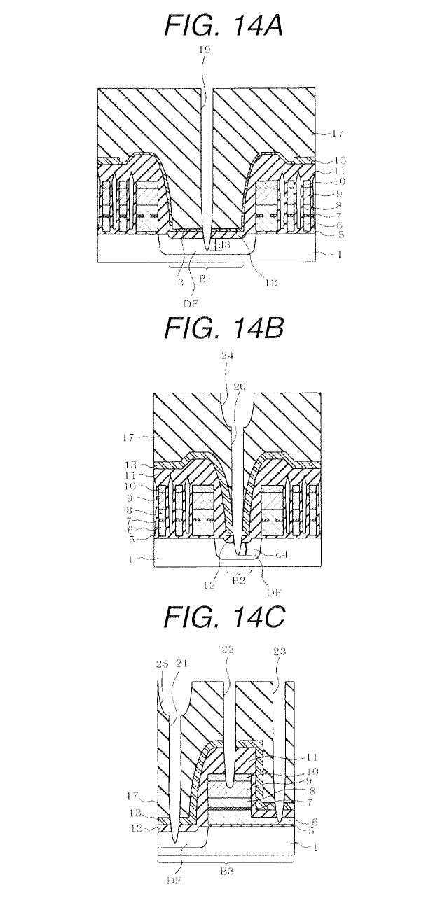

Next, as shown in FIGS. 14A to 14C, using the RIE method, a process of further engraving the hole 19 for the bit line contact CB, the line-shaped groove 20 for the source line contact CS, and the holes 21, 22, and 23 for the three contacts C1, C2, and C3 in the peripheral circuit region (second process) is performed. A depth d3 of the hole 19 engraved on the silicon substrate 1 is substantially the same as a depth d4 of the line-shaped groove 20 for the source line contact CS engraved on the silicon substrate 1. Here, the bottom portion of the hole 19 for the bit line contact CB and the bottom portion of the line-shaped groove 20 for the source line contact CS are positioned above the bottom of the diffusion layer DF.

In the configuration, as shown in FIGS. 9A to 14C, a region in which the hole 19 for the bit line contact CB is formed is referred to as B1, and a region in which the line-shaped groove 20 for the source line contact CS is formed is referred to as B2. A region in which the first to third holes 21 to 23 is formed is referred to as B3. Because of geometry of the holes, the etching rate of the groove 20 is greater than the etching rate of the hole 19. According to the above-described configuration, the thickness of the liner silicon nitride film 13 in the region B1 is smaller than the thickness of the liner silicon nitride film 13 in the region B2, and the upper surface of the liner silicon nitride film 13 of the region B1 is lowered, the two depth d3 and d4 can become substantially the same. In addition, the diameters of the holes 21 to 23 are larger than the diameter of the hole 19. That is, the etching rate of the contact holes 21 to 23 is the same as the etching rate of the groove 20. As a result, the depth of the groove 20 and the depths of the holes 21 to 23 engraved in the silicon substrate 1 are substantially the same. Further, when the hole has an elliptical shape, a dimension of a minor axis is referred to as its diameter.

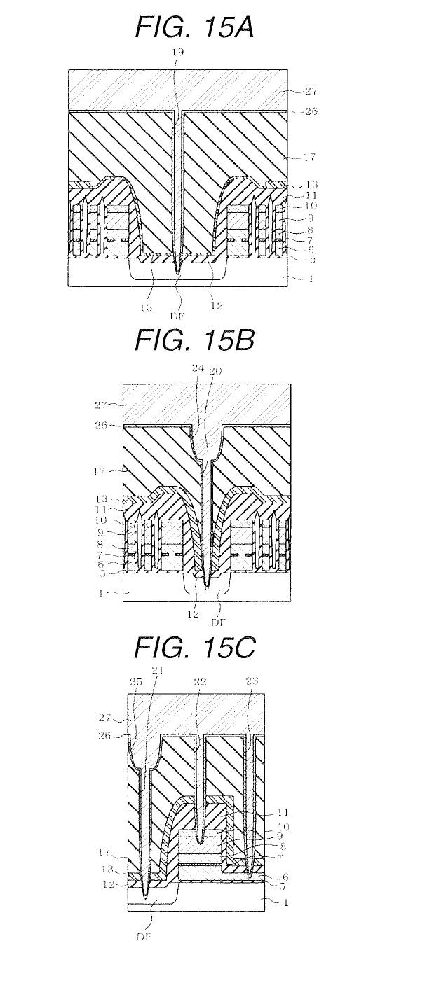

Next, the barrier metal 26 is formed on the inner surfaces of the hole 19 for the bit line contact CB, the line-shaped groove 20 for the source line contact CS, and the holes 21, 22, and 23 for the three contacts C1, C2, and C3 in the peripheral circuit region, and on an upper surface of first interlayer insulating film 17 (refer to FIGS. 15A to 15C). Then, for example, the tungsten film 27 is formed on the barrier metal 26 and conductors (W) are embedded in the holes 19, 21, 22, and 23 and groove 20 (FIGS. 15A to 15C). Further, as shown in FIGS. 16A to 16C, the tungsten film 27 is processed using the CMP method until the upper surface of the first interlayer insulating film 17 is exposed. Thus, a bit line contact plug, a word line contact plug, and a peripheral circuit region contact plug are formed. Thereafter, manufacturing continues to a multilayer wiring process for upper layers although the process is not shown in the drawings.

According to the above-described first embodiment, as shown in FIGS. 9A to 9C, the process of reducing the thickness of the liner silicon nitride film 13 formed on the bottom and side surfaces in the concave portion 15, the upper surface above the select gate electrode SG, and the upper surface above the gate electrode MG is performed. Through this process, the upper surface of the liner silicon nitride film 13 in the region B1 can be positioned lower than the upper surface of the silicon nitride film 13 in the regions B2 and B3. That is, as shown in FIGS. 11A to 11C, a distance from the upper surface of the first interlayer insulating film 17 to the upper surface of the liner silicon nitride film 13 in the region B1 can be adjusted to be longer than a distance from the upper surface of the first interlayer insulating film 17 to the upper surface of the liner silicon nitride film 13 in the regions B2 and B3. Therefore, when the hole 19 for the bit line contact CB and the line-shaped groove 20 for the source line contact CS are processed as shown in FIGS. 12A to 12C, the hole 19 may be engraved more than the groove 20. Thus, the influence of micro loading effect may be reduced in the process shown in FIGS. 14A to 14C, and a difference between the depths of the hole 19 and groove 20 (difference in engraved amount) due to a difference in pattern can be reduced. During the etching of the liner silicon nitride film 13 and the liner silicon oxide film 12 as shown in FIGS. 14A to 14C, since these films are thin, influence of micro loading effect is small. That is, as shown in FIGS. 14A to 14C, when the second process of further engraving the hole 19 and the line-shaped groove 20 is performed, the depth d3 of the hole 19 engraved in the silicon substrate 1 is substantially the same as the depth d4 of the line-shaped groove 20 engraved in the silicon substrate 1. Therefore, when different patterns, that is, the hole 19 and the groove 20 are processed, the depths of the different patterns can be made substantially the same. Accordingly, since the etching amount of the silicon substrate 1 under the groove 20 is much smaller than in the related configuration, junction leak may be prevented.

In addition, also in the peripheral circuit region, a depth of the hole 21 engraved in the silicon substrate 1 is also substantially the same as the depths d3 and d4. As a result, junction leak may be prevented also in the peripheral circuit region.

In addition, a distance from the upper surface of the silicon substrate 1 to the upper surface of the liner silicon nitride film 13 in the bit line region (drain-side region) is shorter than a distance from the upper surface of the silicon substrate 1 to the upper surface of the liner silicon nitride film 13 in the source-side region. However, during the etching process shown in FIGS. 15A to 15C, since the groove 20 and the first to third holes 21 to 23 are formed in a line or have large diameters, after the upper surface of the liner silicon nitride film 13 is exposed, the groove and the holes are etched faster than the hole 19. As a result, the two depth d3 and d4 can be adjusted to be the same.

Further, during the etching process shown in FIGS. 12A to 12C, since the hole 19 has a small diameter, even when the upper surface of the liner silicon nitride film 13 is exposed, the subsequent etching is not easily performed. As a result, even when the thickness of the liner silicon nitride film 13 under the hole 19 is smaller than the thickness of the liner silicon nitride film 13 under the groove 20, the liner silicon nitride film 13 under the hole 19 is not easily penetrated.

During the etching process shown in FIGS. 13A to 13C, the bottom portion of the hole 22 is positioned on the upper surface of the tungsten film 9. However, the bottom of the hole 22 may be positioned in the tungsten film 9 by adjusting an etching ratio of the tungsten film 9 and the liner silicon nitride film 13, or the liner silicon oxide film 12 in FIG. 14C.

### Second Embodiment

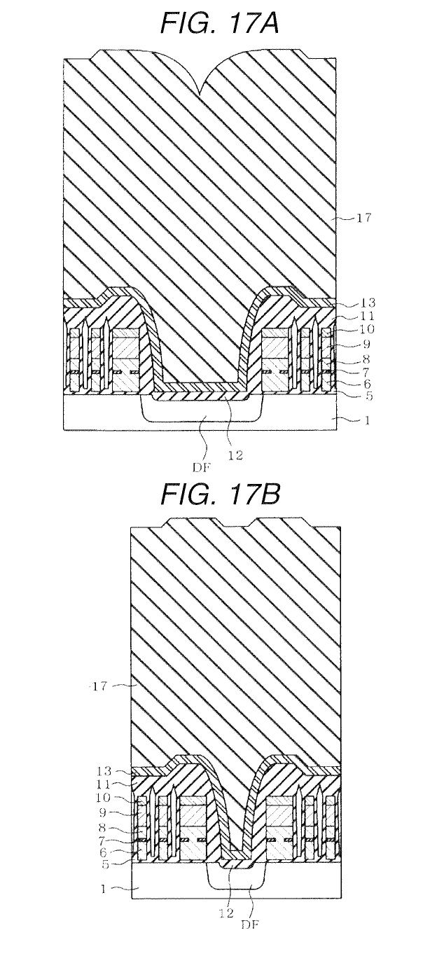

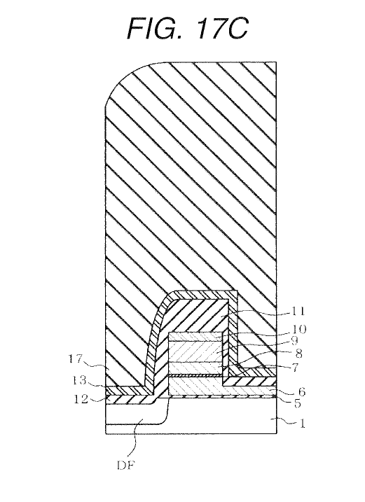

FIGS. 17A to 25C each correspond to one of steps for manufacturing a semiconductor device according to a second embodiment. In addition, the same reference numerals are used for elements that are the same as those in the first embodiment. In the second embodiment, unlike the first embodiment, a hole 29 for the bit line contact CB, a line-shaped groove 30 for the source line contact CS, holes 31, 32, and 33 for the three contacts C1, C2, and C3 in the peripheral circuit region are formed by a process without reducing the thickness of the liner silicon nitride film 13. The process in the second embodiment will be described in detail below.

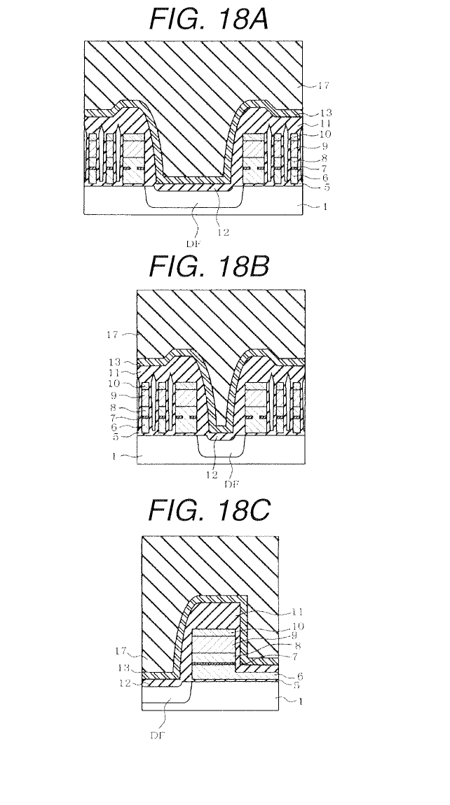

In the second embodiment, first, the processes of FIGS. 3A to 7C in the first embodiment are performed in the same manner as in the first embodiment. Then, after the process of FIGS. 7A to 7C (process of forming the liner nitride film 13), as shown in FIGS. 17A to 17C, the NSG film 17 is formed, as the first interlayer insulating film, on the liner silicon nitride film 13. Further, for example, the first interlayer insulating film 17 is formed thereon as a second interlayer insulating film. Then, as shown in FIGS. 18A to 18C, the upper surface of the first interlayer insulating film 17 is flattened using the CMP method.

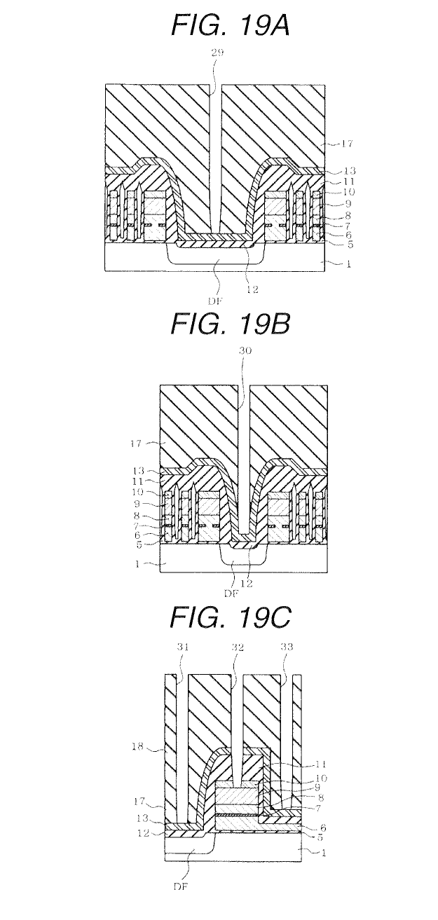

Subsequently, various contact patterns, that is, a hole pattern for the bit line contact CB, a groove pattern for the source line contact CS, and a hole pattern for the three contacts C1, C2, and C3 in the peripheral circuit region are formed using the lithography method, and then, the first interlayer insulating film 17 is processed (FIGS. 19A to 19C) using the RIE method. Thus, as shown in FIGS. 19A to 19C, the hole 29 for the bit line contact CB, the line-shaped groove 30 for the source line contact CS, and the holes 31, 32 and 33 for the three contacts C1, C2, and C3 in the peripheral circuit region are formed.

Through the etching of the first interlayer insulating film 17, the hole 29 for the bit line contact CB is formed so that the etching is stopped on the upper surface of the liner silicon nitride film 13 (not processed to be thin). Further, the line-shaped groove 30 for the source line contact CS is formed so as to reach the upper surface of the liner silicon nitride film 13. Regarding the holes 31, 32, and 33 for the three contacts C1, C2, and C3 in the peripheral circuit region, the hole 31 for the first contact C1 is formed so as to reach the upper surface of the liner silicon nitride film 13. The hole 32 for the second contact C2 is formed so as to reach the upper surface of the tungsten film 9, penetrating the liner silicon nitride film 13, the silicon oxide film 11, the cap film 10. The hole 33 for the third contact C3 is formed so as to reach the upper surface of the liner silicon nitride film 13. The upper surface of the liner silicon nitride film 13 exposed by the holes 29, 31, and 33 and the groove 30 may be recessed.

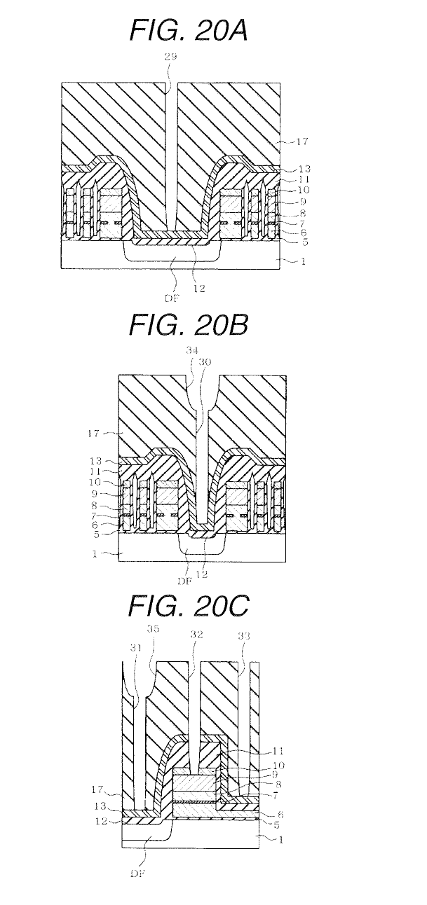

Then, using the lithography method, a pattern for forming a groove 34 for the wiring is formed in the upper portion of the line-shaped groove 30 for the source line contact CS, and a groove 35 for the wiring is formed in the upper portion of the hole 31 of the first contact C1 in the peripheral circuit region is formed. Then, the first interlayer insulating film 17 is processed using the RIE method (refer to FIGS. 20A to 20C).

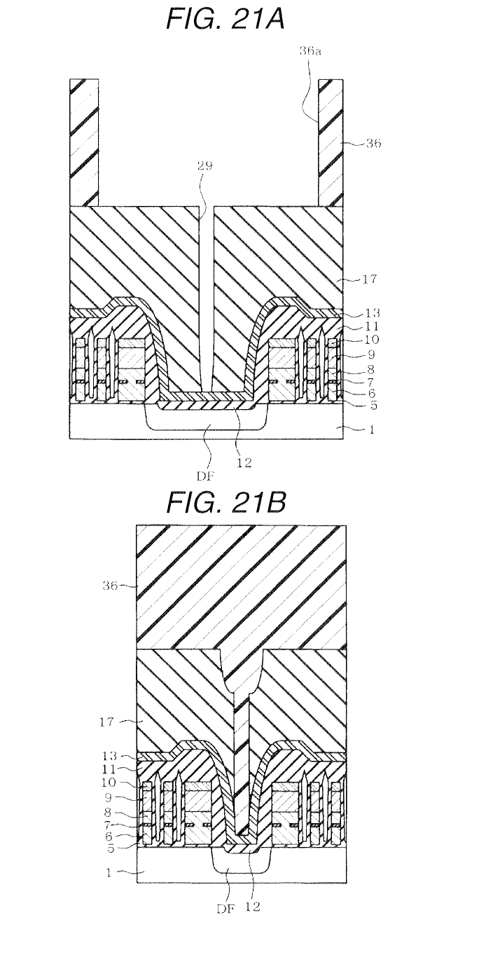

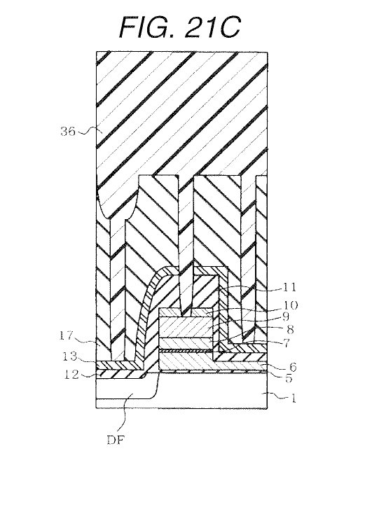

Then, a resist 36 (FIGS. 21A to 21C) is formed. Then, as shown in FIGS. 21A to 21C, an opening portion 36a which is opened so as to correspond to the drain region, that is, the region for forming the bit line contact CB, is formed in the resist 36 using the photolithography method. Here, the opening portion 36a corresponds also to the select gate electrode SG of the select gate transistor adjacent to the bit line contact CB and the gate electrode MG of the memory cell transistor adjacent to the select gate electrode SG on the surface of the silicon substrate 1. Further, the source region, that is, the line-shaped groove 30 for the source line contact CS and the peripheral regions are covered by the resist 36 (FIG. 21B). In addition, the holes 31, 32, and 33 for the three contacts C1, C2, and C3 in the peripheral circuit region and the peripheral regions are covered by the resist 36 (FIG. 21C).

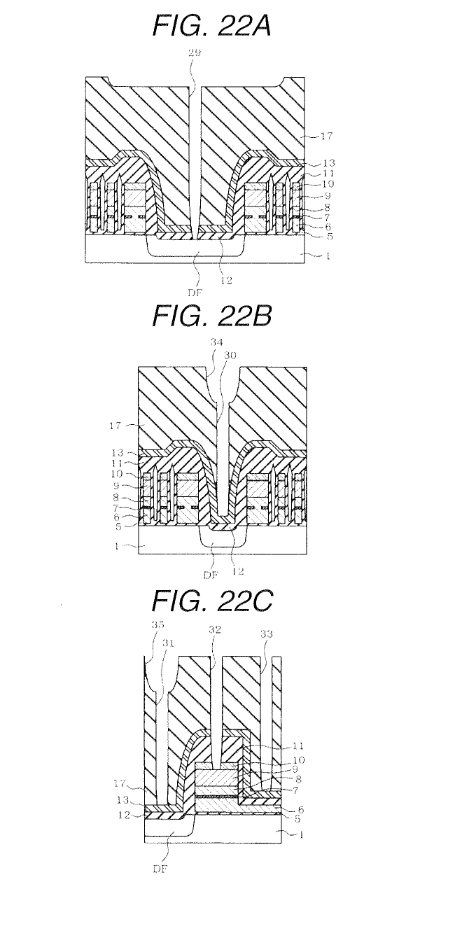

Next, as shown in FIG. 22A, using the RIE method, a process of further engraving the drain region, that is, the hole 29 for the bit line contact CB (pre-engraving process) is performed. In this case, the hole 29 for the bit line contact CB is processed so as to reach the upper surface of the silicon substrate 1, penetrating the liner silicon nitride film 13 and the liner silicon oxide film 12. Thereafter, when the resist 36 is removed, a configuration shown in FIGS. 22A to 22C can be obtained.

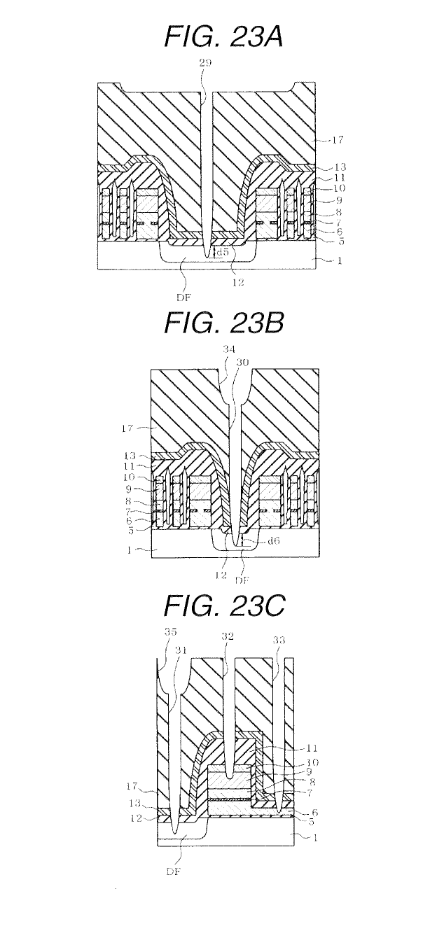

Next, as shown in FIGS. 23A to 23C, using the RIE method, a process of further engraving the hole 29 for the bit line contact CB, the line-shaped groove 30 for the source line contact CS, and the holes 31, 32, and 33 for the three contacts C1, C2, and C3 in the peripheral circuit region is performed. Due to the process, a depth d5 of the hole 29 for the bit line contact CB engraved in the silicon substrate 1 is substantially the same as a depth d5 of the line-shaped groove 30 for the source line contact CS engraved in the silicon substrate 1. In this case, since only the hole 29 for the bit line contact CB is engraved in advance in the process of FIGS. 22A to 22C, the two depths d5 and d6 can be substantially the same.

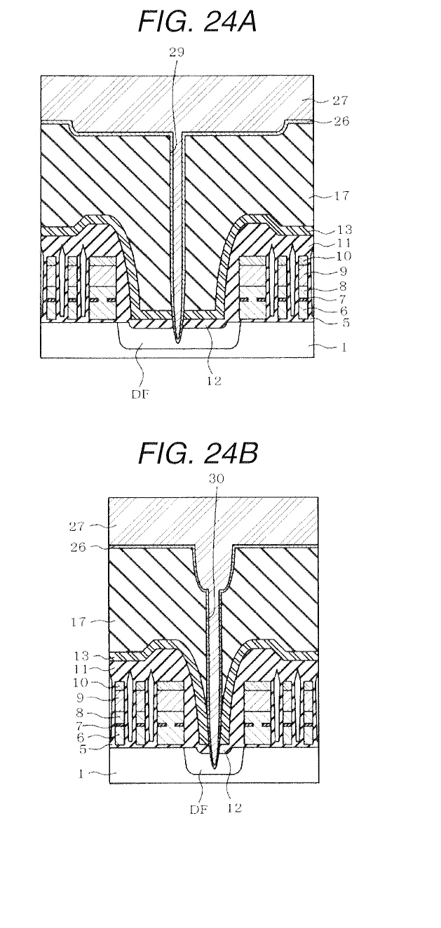

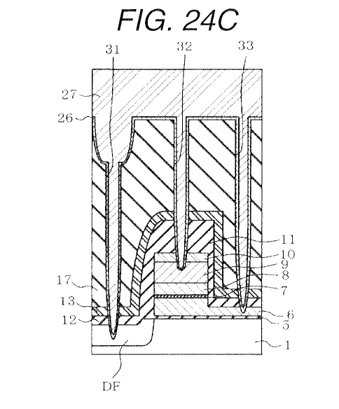

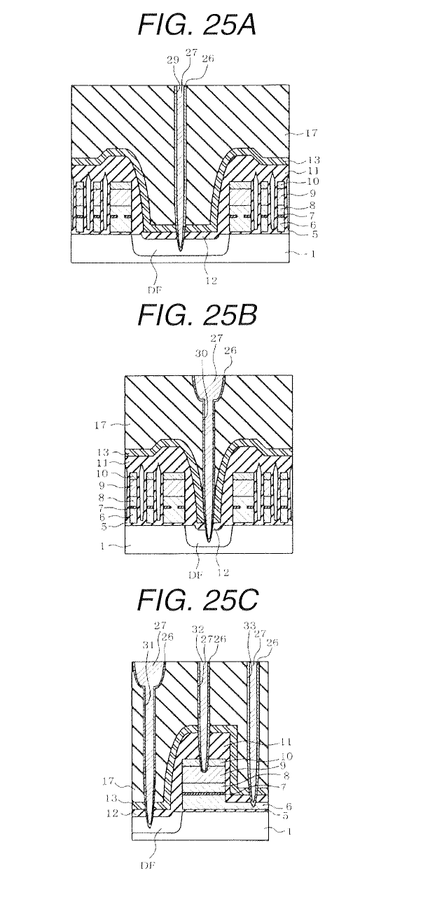

Subsequently, the barrier metal 26 is formed on each inner surface of the hole 29 for the bit line contact CB, the line-shaped groove 30 for the source line contact CS, and the holes 31, 32, and 33 for the three contacts C1, C2, and C3 in the peripheral circuit region, and on the upper surface of the first interlayer insulating film (FIGS. 24A to 24C). Then, for example, the tungsten film 27 is formed on the barrier metal 26 and conductors (W) are embedded in the holes 29, 31, 32, and 33 and groove 30 (FIGS. 24A to 24C). Further, as shown in FIGS. 25A to 25C, the tungsten film 27 is processed using the CMP method until the upper surface of the first interlayer insulating film 17 is exposed. As a result, a bit line contact plug, a word line contact plug, and a peripheral circuit region contact plug are formed.

The configuration of the semiconductor device according to the second embodiment is the same as the configuration of the semiconductor device according to the first embodiment except the aforementioned processes. Accordingly, substantially the same effect as in the first embodiment may be obtained even in the second embodiment.

### Other Embodiments

In addition to the above-described plural embodiments, the following configurations may be adopted.

In the first embodiment, the thickness of the liner silicon nitride film 13 in the concave portion 15 is reduced such that the upper surface of the liner silicon nitride film 13 in the concave portion 15 is lower than the upper surface of the liner silicon nitride film 13 in the concave portion 16. However, there is no limitation thereto. For example, the thickness of the liner silicon nitride film 13 in the concave portion 15 may be the same as the thickness of the liner silicon nitride film 13 in the concave portion 16, and the thickness of the liner silicon oxide film 12 in the concave portion 15 may be thinner than the thickness of the liner silicon oxide film 12 in the concave portion 16. Thus, the upper surface of the liner silicon nitride film 13 in the concave portion 15 may be lower than the upper surface of the liner silicon nitride film 13 in the concave portion 16. In such a configuration, substantially the same effect as in the first embodiment can be obtained.

In addition, in the first embodiment, when the thickness of the liner silicon nitride film 13 in the concave portion 15 is reduced, the liner silicon nitride film 13 in the concave portion 15 is etched. Instead, the entire liner silicon nitride film 13 in the concave portion 15 may be removed and then, a thin liner silicon nitride film 13 may be formed.

Further, in the above-described embodiments, the holes 19 and 29 for the bit line contact CB and the line-shaped grooves 20 and 30 for the source line contact CS are formed at the same time, but they are not limited thereto. For example, the embodiments may be applied to a process of opening holes of patterns (two or more kinds of patterns) having different cross-sectional areas at the same time.

As described above, in the manufacturing of the semiconductor device according to the embodiments, when a process of opening different patterns, for example, hole patterns (holes 19 and 29) having different cross-sectional areas and groove patterns (grooves 20, 21 and 30) is performed, the depths of the different patterns can be adjusted to be substantially the same.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
memory cell units, each including memory cell transistors arranged in a first direction above a substrate, a first transistor at a first end of the memory cell transistors, and a second transistor at a second end of the memory cell transistors, the memory cell units being arranged so that adjacent memory cell units have first transistors thereof facing each other in the first direction or second transistors thereof facing each other in the first direction, and so that a distance between the first transistors of the adjacent memory cell units is larger than a distance between the second transistors of the adjacent memory cell units;
a first silicon nitride layer covering a first diffusion layer of the first transistors;
a second silicon nitride layer covering a second diffusion layer of the second transistors;
a source line electrically connected to at least one of the first transistors and the first diffusion layer;
a bit line electrically connected to at least one of the second transistors and the second diffusion layer;
a first contact electrically connecting the source line to the first diffusion layer; and
a second contact electrically connecting the bit line to the second diffusion layer,
wherein a thickness of the second silicon nitride layer over the second diffusion layer is smaller than a thickness of the first silicon nitride layer over the first diffusion layer.

2. The semiconductor device according to claim 1, wherein
the first silicon nitride layer is formed over sidewalls of gate electrodes of the first transistors, and the second silicon nitride layer is formed over sidewalls of gate electrodes of the second transistors, and
a thickness of the second silicon nitride layer formed over the sidewalls of the gate electrodes of the second transistor is smaller than a thickness of the first silicon nitride layer formed over the sidewalls of the gate electrodes of the second transistors.

3. The semiconductor device according to claim 1, wherein the first contact has a groove shape and extends in a second direction crosswise to the first direction.

4. The semiconductor device according to claim 3, wherein the second contact has a circular shape.

5. The semiconductor device according to claim 1, wherein
a part of the first contact and a part of the second contact are disposed in the substrate, and
a length of the first contact part disposed in the substrate and a length of the second contact part disposed in the substrate are substantially the same.

6. The semiconductor device according to claim 1, wherein
a level of an upper surface of the first diffusion layer is equal to a level of an upper surface of the second diffusion layer.

7. The semiconductor device according to claim 1, further comprising:
a peripheral element having a first gate electrode; and
a third silicon nitride layer covering a third diffusion layer adjacent to the first gate electrode;
wherein the thickness of the second silicon nitride layer formed over the second diffusion layer is smaller than a thickness of the third silicon nitride layer formed over the third diffusion layer.

8. A semiconductor device, comprising:
memory cell units, each including memory cell transistors arranged in a first direction above a substrate, a first transistor at a first end of the memory cell transistors, and a second transistor at a second end of the memory cell transistors, and the memory cell units being arranged so that adjacent memory cell units have first transistors thereof facing each other in the first direction or second transistors thereof facing each other in the first direction, and so that a distance between the first transistors of the adjacent memory cell units is larger than a distance between the second transistors of the adjacent memory cell units;
a first silicon nitride layer covering a first diffusion layer of the first transistors;
a second silicon nitride layer covering a second diffusion layer of the second transistors;
a source line electrically connected to at least one of the first transistors and the first diffusion layer;
a bit line electrically connected to at least one of the second transistors and the second diffusion layer;
a first contact electrically connecting the source line to the first diffusion; and
a second contact electrically connecting the bit line to the second diffusion layer;
wherein a thickness of the second silicon nitride layer over the first diffusion layer is equal to a thickness of the first silicon nitride layer over the first diffusion layer.

9. The semiconductor device according to claim 8, wherein
the first silicon nitride layer is formed over sidewalls of gate electrodes of the first transistors, and the second silicon nitride layer is formed over sidewalls of gate electrodes of the second transistors, and
a thickness of the second silicon nitride layer formed over the sidewalls of the gate electrodes of the second transistor is equal to a thickness of the first silicon nitride layer formed over the sidewalls of the gate electrodes of the second transistors.

10. The semiconductor device according to claim 8, wherein the first contact has a groove shape and extends in a second direction crosswise to the first direction.

11. The semiconductor device according to claim 10, wherein the second contact has a circular shape.

12. The semiconductor device according to claim 8, wherein
a part of the first contact and a part of the second contact are disposed in the substrate, and
a length of the first contact part disposed in the substrate and a length of the second contact part disposed in the substrate are substantially the same.

13. The semiconductor device according to claim 8, wherein
a level of an upper surface of the first diffusion layer is equal to a level of an upper surface of the second diffusion layer.

14. The semiconductor device according to claim 8, further comprising:
a peripheral element having a first gate electrode; and
a third silicon nitride layer covering a third diffusion layer adjacent to the first gate electrode;
wherein the thickness of the second silicon nitride layer formed over the second diffusion layer is equal to a thickness of the third silicon nitride layer formed over the third diffusion layer.

15. A method for manufacturing a semiconductor device, comprising:
forming memory cell transistors arranged in a first direction and a second direction on a substrate;
forming first transistors arranged in the first direction, each of the first transistors formed at a first end of a group of the memory cell transistors;
forming second transistors arranged in the first direction, each of the second transistors formed at a second end of the group of the memory cell transistors;
forming a silicon nitride layer between the first transistors and between the second transistors;
etching only the silicon nitride layer between the first transistors so that a thickness of the silicon nitride layer between the first transistors is smaller than that of the silicon nitride layer between the second transistors;
forming a dielectric layer above the silicon nitride layer;
forming a contact hole between the first transistors and a groove between the second transistors at the same time so as to etch the silicon nitride layer; and
burying a conductive material in the contact hole and the groove.

16. The method according to claim 15, wherein
the forming of the contact hole and the groove includes:
etching the dielectric layer using the silicon nitride layer as a stopper; and
etching the silicon nitride layer so as to penetrate the silicon nitride layer.

17. The method according to claim 16, wherein
the forming of the contact hole and the groove further includes:
etching the substrate after etching the silicon nitride layer so that a level of a bottom of the contact hole is equal to a level of a bottom the groove.
